(19) United States
(12) Patent Application Publication
(10) Pub. No.: US 2026/0242929 A1
(43) Pub. Date: Aug. 20, 2026

(54) EVAPORATION SOURCE FOR VACUUM EVAPORATION APPARATUS AND VACUUM EVAPORATION METHOD

(71) Applicant: ULVAC, INC., Kanagawa (JP)

(72) Inventors: Takahito KIMOTO, Kanagawa (JP); Masashi YASUDA, Kanagawa (JP); Toshiharu KURAUCHI, Kanagawa (JP); Masatoshi SATO, Kanagawa (JP)

(73) Assignee: ULVAC, INC., Kanagawa (JP)

(21) Appl. No.: 19/471,812

(22) PCT Filed: Dec. 28, 2023
(86) PCT No.: PCT/JP2023/047180

§ 371 Date: Oct. 2, 2025

(30) Foreign Application Priority Data
Apr. 5, 2023 (JP) 2023-061224

(51) Int. Cl. C23C 14/24; C23C 14/14

(52) U.S. Cl. CPC C23C 14/243; C23C 14/14

(57) ABSTRACT

An evaporation source for a vacuum evaporation apparatus is provided, which can evaporate an aluminum film at a low cost and a relatively high film formation speed without deteriorating a function that suppresses sudden boiling. An evaporation boat installed inside a vacuum chamber and a power source applying electric current to the evaporation boat are provided. An evaporation material consisting of aluminum is continuously or intermittently fed into the heated crucible, and the evaporation material is melted and vaporized in the crucible. The evaporation boat is made of ceramic, and contains an additive metal material consisting of at least one metal element selected from the group consisting of titanium, tantalum, zirconium, hafnium, and niobium, so that, when the evaporation material is melted in the crucible, the at least one metal element is dissolved into a molten metal of the evaporation material.

### TECHNICAL FIELD

The invention relates to an evaporation source for a vacuum evaporation apparatus, the evaporation source including a crucible installed in a vacuum chamber and a heater for heating the crucible, in which an evaporation material consisting of aluminum is continuously or intermittently fed into the heated crucible, and the evaporation material is melted and vaporized in the crucible, so that an aluminum film is evaporated onto a to-be-evaporated article, as well as a vacuum evaporation method.

### BACKGROUND ART

Recently, an aluminum (Al) film has been used for various uses, such as electrodes of display devices or functional thin films, wiring of printed wiring boards, and thin films for controlling optical properties and molecular permeation. The vacuum evaporation apparatus is used for evaporated formation of the aluminum film. As an evaporation source installed in the vacuum chamber of the vacuum evaporation apparatus, an evaporation source provided with a crucible made of graphite and heater for inductively heating an evaporation material filled in the crucible, or an evaporation source provided with an evaporation boat and a power source for applying an electric current to the evaporation boat, is generally used. When forming the aluminum film onto a to-be-evaporated article using the vacuum evaporation apparatus, not only a quality of the aluminum film but also improvement of a film formation speed (productivity) is strongly demanded. In such a case, a large current is applied to the evaporation boat, and the evaporation boat is heated to a high temperature by Joule heat generated thereby. Meanwhile, in a case where sudden boiling (splash) occurs in a molten metal of the evaporation material, which has melted, wetted and spread, during evaporation, the quality of the aluminum film cannot be maintained at a high level. It has been known that elements and compounds contained in the crucible are released in a vapor phase, which is one of the causes of sudden boiling.

Conventionally, for example, a method described in Patent Document 1 has been known as a method of suppressing sudden boiling mentioned above when forming a gold (Au) film onto the to-be-evaporated article, for example. In this method, at least one metal element selected from the group consisting of tantalum (Ta), zirconium (Zr), hafnium (Hf), and niobium (Nb), added to Au in a predetermined weight ratio, is the evaporation material. Thus, the evaporation material is accommodated in a crucible produced by sintering high-temperature metals such as tungsten or molybdenum, and the at least one metal element is dissolved into a molten metal of Au when Au is melted by heating the crucible. Accordingly, when impurities such as oxygen and oxides derived from tungsten or molybdenum is released in the molten metal in the vapor phase, this impure gas reacts with a metal serving as a gettering material react. Since a reaction product generated at this time has a significantly lower vapor pressure than Au (for example, 1/10000) at a heating temperature of the crucible during evaporation, the occurrence of sudden boiling can be suppressed. Besides, the at least one metal and the reaction product are dissolved into the evaporated Au film. No defects, such as those causing a decrease in the quality of the film, occur.

By the way, an evaporation boat produced by sintering raw materials containing boron nitride and titanium boride, which provides conductivity to the crucible, is used as an evaporation boat for evaporation of the Al film. When a relatively large electric power is applied to such an evaporation boat to heat it at a high temperature (in a range of 1200° C. to 1500° C.), it has been confirmed that an element, such as boron, contained in the crucible and an impurity, such as oxygen, which is inevitably contained in the crucible at the time of its production, is released in the vapor phase. Therefore, in a case where the aluminum film is also formed at a high film formation speed using the vacuum evaporation apparatus, it is considered that the occurrence of sudden boiling is suppressed by applying the conventional method.

Meanwhile, in a case where the Al film is effectively formed over a long period of time, the evaporation material is formed into a wire having a predetermined outer diameter, and while the wire is fed from above the evaporation boat, the evaporation material is melted in the evaporation boat. However, production of a dedicated evaporation material by adding a metal element serving as a gettering material to Al as a raw material and further forming into the wire shape brings about not only an increase in product cost but also a lack of versatility. Besides, it is actually difficult to keep a weight ratio of the metal element constant over an entire length at the time of production of the wire-shaped evaporation material. Therefore, in a state where the amount of the metal element dissolved into the molten metal is small, sudden boiling in the molten metal may not be effectively suppressed. In addition, in a state where the amount of the metal element dissolved into the molten metal is large, a slag that may cause variation in a temperature of the molten metal (consequently, the film formation speed) may be generated in the molten metal of Al.

### PRIOR ART

### Patent Document

Patent Document 1: JP 6697073 B

### SUMMARY OF INVENTION

### Problem that the Invention is to be Solved

The invention has been made in view of the points mentioned above, and addresses a problem of providing an evaporation source for a vacuum evaporation apparatus, which can evaporate the aluminum film at a low cost and a relatively high film formation speed without deteriorating a function that suppresses sudden boiling, as well as a vacuum evaporation method.

### Means for Solving the Problem

In order to address the problem mentioned above, the invention provides an evaporation source for a vacuum evaporation apparatus, the evaporation source including a crucible installed in a vacuum chamber and a heater for heating the crucible, in the vacuum evaporation apparatus, an evaporation material consisting of. aluminum is continuously or intermittently fed into the heated crucible, and the evaporation material is melted and vaporized in the crucible, so that an aluminum film is evaporated onto a to-be-evaporated article, the evaporation source comprising: a crucible made of a ceramic containing an additive metal material consisting of at least one metal element selected from the group consisting of titanium, tantalum, zirconium, hafnium, and niobium, wherein, when the evaporation material is melted in the crucible, the at least one metal element is configured to dissolve into a molten metal of the evaporation material.

According to the invention, when the crucible is heated within a predetermined temperature range inside the vacuum chamber in a vacuum atmosphere, and aluminum (Al) is continuously or intermittently fed from above into the crucible, Al is melted, wetted, and spread in the crucible, and this wetted and spread molten Al is vaporized to evaporate (form) the aluminum film. At this time, since the at least one metal element contained in the crucible is dissolved into the molten Al, even though an element contained in the crucible or an inevitably contained impurity is released in the molten metal in a vapor phase, the impurity gas reacts with a metal element serving as a gettering material. Since a reaction product generated by the reaction with the impurity gas has a vapor pressure significantly lower than that of Al at a heating temperature of the crucible during the evaporation, and together with suppression of formation of a compound (for example, boron oxide) having a vapor pressure higher than that of Al, a function of suppressing sudden boiling is not damaged. In addition, due to the additive metal material contained in the ceramic crucible itself, it is not especially necessary to use a dedicated evaporation material, and thus low cost can be achieved.

Here, according to the inventors' extensive research, for example, in a case where a metal foil made of the at least one metal element mentioned above is laid on a ceramic evaporation boat, and the evaporation boat is heated within the temperature range mentioned above by applying electric current to the evaporation boat inside the vacuum chamber in the vacuum atmosphere, the metal foil melts only slightly. On the other hand, in a case where the evaporation material is fed and Al is melted in the evaporation boat, and the molten Al, which is melted, wetted, and spread, contacts the metal foil, it has been found that the metal foil melts and the at least one metal element dissolves into the molten metal, without significantly changing a pressure inside the vacuum chamber or the heating temperature. Then, in the invention, the additive metal material is formed into a foil, a wire, or a grain, and the at least one metal material is laid on the crucible in advance of evaporation onto the to-be-evaporated article, so that, when the evaporation material is melted, wetted, and spread, the at least one metal material contacts this molten metal. According to this, a configuration for suppressing the occurrence of sudden boiling can be easily achieved. Besides, even if the metal element reacting with the impurity gas is depleted by repeating evaporation onto the to-be-evaporated article over a long period of time, only the additive metal material needs to be additionally laid on the crucible, which is advantageous.

In addition, in the invention, it is preferable that the additive metal material be titanium, and that the crucible be formed by sintering a raw material containing boron nitride and titanium nitride. Here, as seen from an Al—Ti binary diagram, a maximum weight ratio of Ti dissolving into the molten Al is approximately 20 wt % within the temperature range mentioned above. Therefore, a weight of the metal foil to be laid needs to be set on basis of a volume of the molten Al during evaporation. Even if the additive metal material is laid in an amount exceeding the above weight ratio, it has been confirmed that occurrence of slag in the molten Al is not observed, that although a vapor pressure of titanium is higher than those of other metal elements, no defect arises in which Ti or a reaction product thereof (such as titanium oxide) dissolves into the evaporated Al film, and that a quality of the Al film is not impaired. Furthermore, when titanium is selected as an additive metal element, the reaction product generated by reacting with titanium mainly becomes titanium boride, which is one of the components contained in the crucible. Formation of a compound (such as boron oxide) having a vapor pressure higher than that of Al is suppressed by covering a surface of the evaporation boat, where Al wets and spreads, with titanium boride, which can further suppress the occurrence of sudden boiling.

Furthermore, in order to address the problem mentioned above, the invention provides A vacuum evaporation method for evaporating an aluminum film onto a to-be-evaporated article Sg by heating a crucible 3 installed in a vacuum chamber 1, feeding an evaporation material Em made of aluminum into the crucible continuously or intermittently, and melting and vaporizing the evaporation material in the crucible, characterized in that: a ceramic crucible is used, and the vacuum evaporation method comprises a step of laying an additive metal material 7 consisting of at least one metal element selected from the group consisting of titanium, tantalum, zirconium, hafnium, and niobium on the crucible in advance of evaporation onto the to-be-evaporated article, wherein the additive metal material is configured to contact a molten metal when the evaporation material is melted, wetted, and spread.

### BRIEF DESCRIPTION OF THE DRAWINGS

FIG. 1 is a cross-sectional view of an inline-type vacuum evaporation apparatus provided with an evaporation source according to an embodiment.

FIG. 2A is an enlarged plan view of the evaporation source shown in FIG. 1, and FIG. 2B is an enlarged cross-sectional view of FIG. 2A.

### MODE FOR CARRYING OUT THE INVENTION

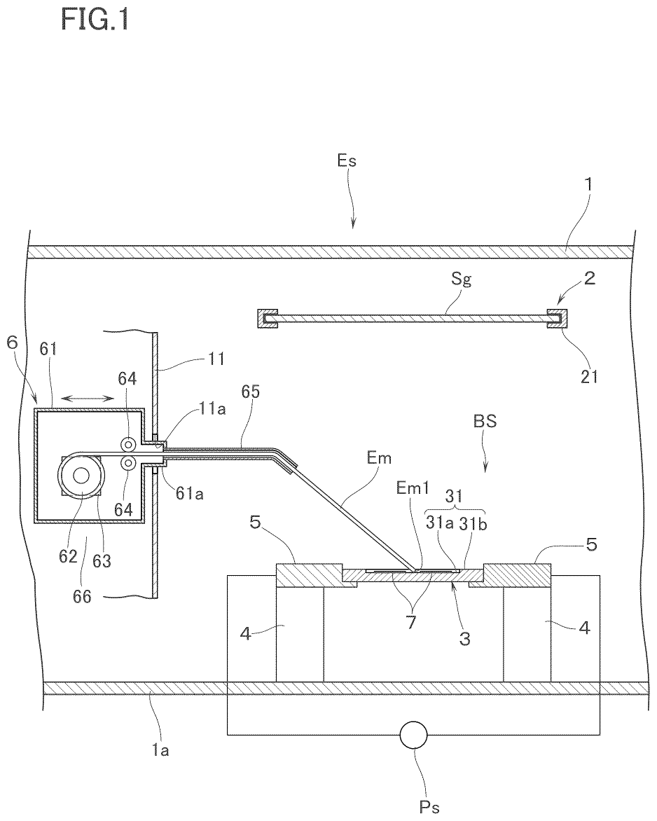

With reference to figures, an embodiment of the deposition source BS for a vacuum deposition apparatus and the vacuum deposition method of the present invention will be described using as an example a case in which the crucible is a deposition boat, the heating means is a power source that applies electricity to the deposition boat to heat it with Joule heat, and the deposition object is a rectangular glass substrate (hereinafter referred to as “substrate Sg”), and wire-shaped deposition material Em made of aluminum is continuously supplied and evaporated in a vacuum chamber in a vacuum atmosphere to deposit an aluminum (Al) film on the film formation surface of the substrate Sg. In the following descriptions, terms indicating directions, such as “up” and “down”, are principally based on FIG. 1, which shows an installed posture of the evaporation source BS.

With reference to FIG. 1, an inline-type vacuum evaporation apparatus Es is provided with a vacuum chamber 1. A vacuum pump is connected to the vacuum chamber 1 via an exhaust pipe (not shown), and can form a vacuum atmosphere inside the vacuum chamber 1 during evaporation. In this case, the inside of the vacuum chamber 1 can be set to maintain within a pressure range from 1×10⁻² Pa to 5×10⁻⁴ Pa. A substrate transporting apparatus 2 is provided in an inner space on an upper side of the vacuum chamber 1. The substrate transporting apparatus 2 has a carrier 21 holding the substrate Sg in a state where a lower surface thereof as an evaporated surface is opened, and can transport the substrate Sg in one direction inside the vacuum chamber 1 at a predetermined speed. Since every known apparatus is applied to the substrate transporting apparatus 2, descriptions beyond the above are omitted. The evaporation source BS of the embodiment is provided an inner surface on a lower side of the vacuum chamber 1, which opposes the substrate Sg transported in one direction.

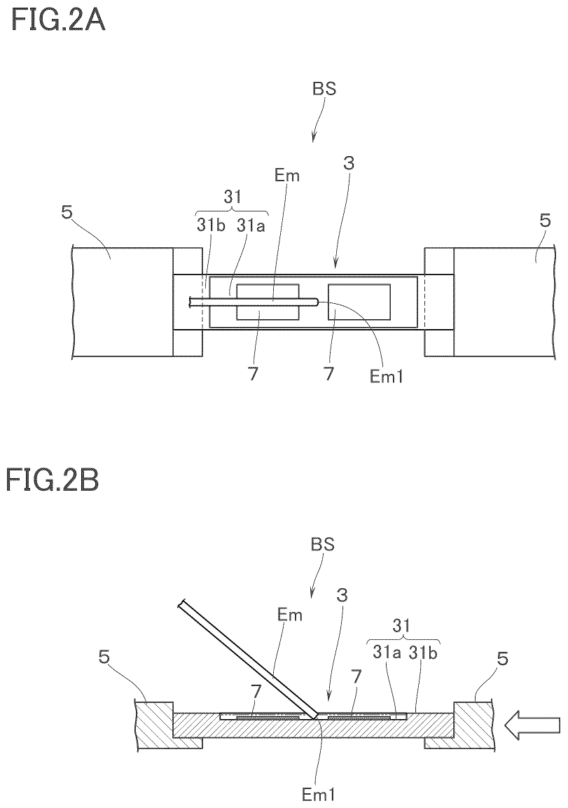

With reference also to FIG. 2 the evaporation source BS is provided with an evaporation boat 3 made of ceramic. The evaporation boat 3 is provided with a boat main body 31 having a recessed part 31a with a flat inner bottom surface. In the evaporation boat 3, an electrode mounting plate part 31b can be formed by each portion of the boat main body 31 extending toward each side in a longitudinal direction (in FIG. 1, right-left hand direction) of the recessed part 31a. For example, the evaporation boat is used as the evaporation boat 3, which is formed by sintering a raw material, in which boron nitride (BN) and titanium boride (TiB₂) for giving electric conductivity to the evaporation boat are main components, and these are contained in a predetermined weight ratio. In this case, in order to give wettability to the evaporation boat, a metal compound such as aluminum nitride can be added to the raw material. Meanwhile, every known method can be used for a sintering method, descriptions beyond the above are omitted.

Two supporting stands 4, 4 formed of an insulation material are mounted on an inner surface of a lower wall 1a of the vacuum chamber 1 by intervals in the longitudinal direction. Each of a right-left and pair of the electrode clamps 5, 5 formed of a metal such as copper having good electric conductivity are mounted on the respective supporting stand 4. The evaporation boat 3 can be detachably held by pressing each electrode mounting plate 31b of the boat main body 31 from each side in the longitudinal direction. In a holding state of the evaporation boat 3, the evaporation boat 3 is installed at a predetermined height position from the inner surface of the lower wall 1a in a posture where a bottom surface of the boat main body 31 is directed horizontally.

A material feeder 6 for continuously feeding the wire-shaped evaporation material Em into the recessed part 31a is provided inside the vacuum chamber 1. The material feeder 6 has a housing 61 installed on a side of the anti-sticking plate 11 opposite to the evaporation source BS, the anti-sticking plate 11 being disposed inside the vacuum chamber 1. A feeding roller 62, a motor 63 rotatably driving the feeding roller 62, and an upper-lower pair of guide rollers 64, 64 are housed in the housing 61. A protruding pipe part 61a is formed on a side wall of the housing 61 positioned on a side of the evaporation source BS, and the housing 61 is installed inside the vacuum chamber 1 so that the protruding pipe part 61a is inserted into a through-hole 11a formed in the anti-sticking plate 11. A guide pipe 65 having a predetermined length and bent into a V-shape is attached to a tip end of the protruding pipe part 61a, and guides the wire-shaped evaporation material Em toward the recessed part 31a. The evaporation material Em is a material in which Al having a purity corresponding to a quality of the Al film to be evaporated is formed into a diameter of φ 1 mm to φ 5 mm, and is wound around the feeding roller 62 in advance. A tip end part Em1 of the wire-shaped evaporation material Em wound around the feeding roller 62 is drawn and passed between the upper-lower pair of guide rollers 64, 64, and is inserted from a space in the protruding pipe part 61a into the guide pipe 65. The wire-shaped evaporation material Em is prepared so that the tip end part Em1 of the evaporation material Em protruding from the guide pipe 65 contacts from above the inner bottom surface of the recessed part 31a at a central region in the longitudinal direction of the recessed part 31a.

In a case where an Al film is evaporated on the lower surface of the substrate Sg inside the vacuum chamber 1 in a vacuum atmosphere by a vacuum evaporation method of the embodiment, electric current is applied between both electrode mounting plates 31b, 31b via the electrode clamps 5, 5 from a power source Ps installed outside the vacuum chamber 1. This allows the boat main body 31 to be heated by Joule heat. An electric power applied at this time is set corresponding to film formation speed when an Al film is evaporated onto the power surface of the substrate Sg. In the embodiment, the electric power is set within a range of 4 kw to 6 kw so that the evaporation boat 3 can be heated within a temperature range of 1200° C. to 1500° C., which allows a high film formation speed to be obtained. At temperatures lower than 1200° C., the wire-shaped evaporation material Em cannot be efficiently melted to achieve a high film formation speed, and at temperatures beyond 1500° C., the wire-shaped evaporation material Em is softened and jammed in the guide pipe 65 due to excessively high ambient temperature, and there is possibility that continuous feeding of the wire-shaped evaporation material Em cannot be smoothly achieved. When the evaporation boat 3 reaches the predetermined temperature, the feeding roller 62 is rotatably driven by the motor 63, and the wire-shaped evaporation material Em is drawn. Thus, the evaporation material Em is melted in the recessed part 31a, and the evaporation material Em in this melted, wetted, and spread molten Al is vaporized, thereby evaporating an Al film onto the lower surface of the substrate Sg moving in the one direction. A feeding speed of the wire-shaped evaporation material Em is set, corresponding to a film formation speed, within a range of 2 g/min to 5 g/min (so that a feeding speed per unit area (cm²) on a molten metal surface becomes within a range of 0.1 g/min to 0.5 g/min, preferably, 0.2 g/min), for example.

Here, when the evaporation boat 3 is heated within the temperature range mentioned above, an impurity, such as boron contained in the evaporation boat 3, or oxygen inevitably contained during production of the evaporation boat 3, is released in a vapor phase. Therefore, it is necessary to avoid occurrence of sudden boiling due to the release of an impurity gas during evaporation. Then, in the embodiment, an additive metal material 7 consisting of at least one metal element selected from the group consisting of titanium, tantalum, zirconium, hafnium, and niobium is formed into a film having a thickness within a range of 0.1 mm to 0.7 mm. In addition, the additive metal material 7 in the foil shape is laid on the inner bottom surface of the recessed part 31a in advance of evaporation, so that, when the evaporation material Em is melted, wetted, and spread by heating the evaporation boat 3, the additive metal material 7 contacts a molten metal (a step of laying the additive metal material on the crucible in the vacuum evaporation method of the embodiment). Specifically, one additive metal material 7 is laid on each side except an ambient region of the inner bottom surface of the recessed part 31a, where the tip end part Em1 of the evaporation material Em contacts. In this case, a weight ratio of the metal element capable of being dissolved into the molten Al within the temperature range mentioned above is obtained from a binary diagram of Al and the other metal element, and a weight of the additive metal materials in the foil shape to be laid may be set on a basis of a volume of the molten Al in the recessed part 31a during evaporation. Meanwhile, it is preferable that the additive metal material 7 be laid in an amount equal to or larger than that weight to prevent depletion of the metal element when evaporation onto the substrate Sg is repeated over a long period of time.

According to the above, when the wire-shaped evaporation material Em is fed from above into the recessed part 31a of the evaporation boat 3 heated inside the vacuum chamber 1 in the vacuum atmosphere, and Al is melted, wetted, and spread in the recessed part 31a, and this wetted and spread molten Al contacts the additive metal material 7 in the foil shape, the additive metal material 7 is melted, and the metal element is dissolved into the molten metal. Thus, even though an impurity, such as boron contained in the evaporation boat 3 or oxygen inevitably contained is released in the molten metal in a vapor phase, this impurity gas reacts with a metal element serving as a gettering material. Since a reaction product generated by the reaction with the impurity gas has a vapor pressure significantly lower than that of Al as the evaporation material Em within the temperature range mentioned above, and together with suppression of formation of a compound (for example, boron oxide) having a vapor pressure higher than that of Al, sudden boiling is suppressed. In addition, since only the additive metal material 7 in the foil shape needs to be laid on the inner bottom surface of the recessed part 31a, it is not especially necessary to produce a dedicated evaporation material containing in the metal element mentioned above as the evaporation material Em, the existing evaporation material is used, and thus low cost can be achieved. Besides, the existing evaporation boat can be also used as the evaporation boat 3. In addition, even when the metal element reacting with the impurity gas is depleted by repeating evaporation onto the substrate Sg, only the additive metal material 7 needs to be additionally laid on the evaporation boat 3.

In addition, even in an case where titanium (Ti) is selected as the additive metal element 7, and the additive metal material 7 is laid in the amount mentioned above for the purpose of preventing depletion of Ti, it has been confirmed that occurrence of slag in the molten Al is not observed, that although a vapor pressure of titanium is higher than those of other metal elements, no defect arises in which Ti or a reaction product thereof (such as titanium oxide) dissolves into the evaporated Al film, and that a quality of the Al film is not impaired. Besides, the reaction product generated by reacting with titanium mainly becomes titanium boride, which is one of the components contained in the evaporation boat 3. Formation of a compound (such as boron oxide) having a vapor pressure higher than that of Al is suppressed by covering the inner bottom surface of the recessed part 31a, where Al wets and spreads, with titanium boride, which can further suppress the occurrence of sudden boiling.

In order to confirm the above effects, the following experiments are performed using the vacuum evaporation apparatus shown in FIG. 1. That is, a square stainless substrate with sides of 200 mm was attached just above at a predetermined distance from the evaporation boat 3 inside the vacuum chamber 1, Al is continuously evaporated for 4 hours under the following evaporation conditions, the amount of sudden boiling was confirmed. As the evaporation boat 3, two types were used: one (Boat 1) formed by mixing BN with TiB₂, both being main raw materials, in a predetermined weight ratio and sintering; and the other (Boat 2) formed by mixing BN and TiB₂ as main raw materials with AlN as an additive material in a predetermined weight ratio and sintering (external dimensions are 38 mm×150 mm×thickness 9 mm).

In addition, four types of additive metal materials 7 were prepared: an Nb foil (1.5 g), a Ta foil (3.6 g), a Ti foil (1.0 g), and a Zr foil (1.9 g). Each foil was laid in advance on the recessed part 31a of the evaporation boat 3. As for the evaporation conditions, the electric power applied to the evaporation boat 3 was 5 KW (corresponding to a heating temperature of approximately 1350° C.), the evaporation material Em was aluminum wire with a diameter of 2 mm, the feeding speed of the evaporation material Em from the feeding roller 62 was set to 3 g/min, and the pressure inside the vacuum chamber 1 during evaporation was maintained at 5×10⁻³ Pa.

In Table 1, measured results of the number of sudden-boiling deposits with a size of 0.05 mm or larger onto the stainless substrate are shown. The number of sudden-boiling deposits was measured using a 10× microscope. When evaporation was performed without laying the additive metal material 7, it was confirmed that the number of sudden-boiling deposits was 10,000 or more (Comparative Example). Conversely, as long as the additive metal material 7 consisting of any of the metal elements was laid in advance, it was confirmed that the sudden-boiling deposits were significantly decreased. Especially, in the case of Ti, which is relatively inexpensive, sudden-boiling deposits with a size of 0.05 mm or larger were not confirmed.

TABLE 1

| Metal element | Boat 1 | Boat 2 |
|---|---|---|
| Nb | 6 | 4 |
| Ta | 3 | 1 |
| Ti | 1 | 0 |
| Zr | 28 | 17 |
| Comparative Exam. | 12100 | 10500 |

Next, when dissolution of each metal element, such as Al, Nb, Ta, Ti, and Zr, in the Al film was observed by XRF, as shown in Table 2, it was confirmed that the dissolution was a detection limit or less and that no dissolution of each metal element occurred.

TABLE 2

| Element | Al | B | Nb | Ta | Ti | Zr |
|---|---|---|---|---|---|---|
| Nb | 0.117 | Detection | Detection | — | Detection | — |
| | | limit or less | limit or less | | limit or less | |
| Ta | 0.118 | Detection | — | Detection | Detection | — |
| | | limit or less | | limit or less | limit or less | |
| Ti | 0.123 | Detection | — | — | Detection | — |
| | | limit or less | | | limit or less | |
| Zr | 0.121 | Detection | — | — | Detection | Detection |
| | | limit or less | | | limit or less | limit or less |
| Comparative | 0.119 | Detection | — | — | Detection | — |
| Exam. | | limit or less | | | limit or less | |

In the embodiments, descriptions mentioned above were made of an example, various modifications are possible as long as the modifications fall within the scope of the technical concept of the invention. In the embodiment mentioned above, although descriptions were made of the example in which, when the evaporation material Em is melted in the evaporation boat 3, the additive metal material 7 in the foil shape is laid on the recessed part 31a of the evaporation boat 3 in advance of evaporation onto the substrate Sg, so that the at least one metal element of titanium, tantalum, zirconium, hafnium, and niobium is contained in the molten metal, the invention is not limited to this. For example, the metal element may be thermally sprayed onto the inner bottom surface of the recessed part 31a, except an ambient region where the tip end Em1 of the evaporation material Em comes into contact, or the evaporation material Em may be provided as a wire or grain having a predetermined diameter. In addition, in the embodiment mentioned above, although descriptions were made of the example in which the evaporation material Em is wire-shaped and the wire-shaped evaporation material Em is fed into the evaporation boat 3, the invention is not limited to this. For example, the invention can be applied to a case where a grain-shaped evaporation material Em is fed into the crucible periodically. Furthermore, in the embodiment mentioned above, although descriptions were made of the example in which the evaporation boat 3 made of ceramic is applied to the crucible, the invention is not limited to this. The invention can be applied to a crucible made of graphite (especially with PBN coated on the inner surface).

### EXPLANATION OF MARKS

BS Evaporation source for vacuum evaporation apparatus
Em Evaporation material (wire-shaped aluminum)
Es Vacuum evaporation apparatus
Sg Substrate (to-be-evaporated article)
1 Vacuum chamber
7 Additive metal material

What is claimed is:

1. An evaporation source for a vacuum evaporation apparatus, the evaporation source including a crucible installed in a vacuum chamber and a heater for heating the crucible, in the vacuum evaporation apparatus, an evaporation material consisting of aluminum is continuously or intermittently fed into the heated crucible, and the evaporation material is melted and vaporized in the crucible, so that an aluminum film is evaporated onto a to-be-evaporated article,
the evaporation source comprising:
a crucible made of a ceramic containing an additive metal material consisting of at least one metal element selected from the group consisting of titanium, tantalum, zirconium, hafnium, and niobium,
wherein, when the evaporation material is melted in the crucible, the at least one metal element is configured to dissolve into a molten metal of the evaporation material.

2. The evaporation source for a vacuum evaporation apparatus according to claim 1, wherein the additive metal material is formed into a foil, a wire, or a grain, and the at least one metal material is laid on the crucible in advance of evaporation onto the to-be-evaporated article, so that, when the evaporation material is melted, wetted, and spread, the at least one metal material contacts this molten metal.

3. The evaporation source for a vacuum evaporation apparatus according to claim 2, wherein the additive metal material be titanium, and that the crucible be formed by sintering a raw material containing boron nitride and titanium nitride.

4. A vacuum evaporation method for evaporating an aluminum film onto a to-be-evaporated article by heating a crucible installed in a vacuum chamber, feeding an evaporation material made of aluminum into the crucible continuously or intermittently, and melting and vaporizing the evaporation material in the crucible,
the vacuum evaporation method, using a ceramic crucible, comprising:
a step of laying an additive metal material consisting of at least one metal element selected from the group consisting of titanium, tantalum, zirconium, hafnium, and niobium on the crucible in advance of evaporation onto the to-be-evaporated article,
wherein the additive metal material is configured to contact a molten metal when the evaporation material is melted, wetted, and spread.
